(19) United States
(12) Patent Application Publication
(10) Pub. No.: US 2025/0164965 A1
(43) Pub. Date: May 22, 2025

(54) SYSTEM AND METHOD FOR PERFORMING 3D PHOTORESIST PROFILE GENERATION

(71) Applicant: Coventor, Inc., Cary, NC (US)

(72) Inventors: Qing Peng Wang, Shanghai (CN); Rui Bao, Shanghai (CN); Cheng Li, Shanghai (CN); Yu De Chen, Tainan City (TW); Shi-hao Huang, Kaohsiung City (TW); Joseph Ervin, Los Gatos, CA (US)

(21) Appl. No.: 18/841,163

(22) PCT Filed: Feb. 24, 2023
(86) PCT No.: PCT/US2023/013761

§ 371 Date: Aug. 23, 2024

Related U.S. Application Data
(60) Provisional application No. 63/313,992, filed on Feb. 25, 2022.

(51) Int. Cl. G05B 19/4093

(52) U.S. Cl. CPC G05B 19/40935; G05B 2219/34122; G05B 2219/35066; G05B 2219/45212

(57) ABSTRACT

Systems and methods for performing 3D photoresist profile generation for a semiconductor device fabrication environment are discussed. The methods comprise receiving in a virtual fabrication environment a top contour mask and a bottom contour mask, creating a loading map using a subset of density information extracted from the top contour mask and the bottom contour mask, performing an etch operation using the loading map to generate the 3D photoresist profile, and outputting a result of the etch operation.

### RELATED APPLICATION

This application claims the benefit of, and priority to, U.S. Provisional Patent Application No. 63/313,992, filed on Feb. 25, 2022, the entire content of which is incorporated herein by reference in its entirety.

### BACKGROUND

Semiconductor development organizations at integrated device manufacturers (IDMs) and independent foundries spend significant resources developing the integrated sequence of process operations used to fabricate the chips (integrated circuits (ICs)) they sell from wafers (“wafers” are thin slices of semiconductor material, frequently, but not always, composed of silicon crystal). A large portion of the resources is spent on fabricating experimental wafers and associated measurement, metrology (“metrology” refers to specialized types of measurements conducted in the semiconductor industry) and characterization structures, all for the purpose of ensuring that the integrated process produces the desired semiconductor device structures. These experimental wafers are used in a trial-and-error scheme to develop individual processes for the fabrication of a device structure and also to develop the total, integrated process flow. Due to the increasing complexity of advanced technology node process flows, a large portion of the experimental fabrication runs result in negative or null characterization results. These experimental runs are long in duration, weeks to months in the “fab” (fabrication environment), and expensive. Recent semiconductor technology advances have dramatically increased the complexity of integrated semiconductor fabrication processes. The cost and duration of technology development using this trial-and-error experimental methodology has concurrently increased.

A virtual fabrication environment for semiconductor device structures offers a platform for performing semiconductor process development at a lower cost and higher speed than is possible with conventional trial-and-error physical experimentation. In contrast to conventional CAD and TCAD environments, a virtual fabrication environment is capable of virtually modeling an integrated process flow and predicting the complete 3D structures of all devices and circuits that comprise a full technology suite. Virtual fabrication can be described in its most simple form as combining a description of an integrated process sequence with a subject design, in the form of 2D design data (masks or layout), and producing a 3D structural model that is predictive of the result expected from a real/physical fabrication run. A 3D structural model includes the geometrically accurate 3D shapes of multiple layers of materials, implants, diffusions, etc. that comprise a chip or a portion of a chip. Virtual fabrication is done in a way that is primarily geometric, however the geometry involved is instructed by the physics of the fabrication processes. By performing the modeling at the structural level of abstraction (rather than physics-based simulations), construction of the structural models can be dramatically accelerated, enabling full technology modeling, at a circuit-level area scale. The use of a virtual fabrication environment thus provides fast verification of process assumptions and visualization of the complex interrelationship between the integrated process sequence and the 2D design data.

### BRIEF SUMMARY

Embodiments of the present invention provide the ability to perform 3D photoresist (PR) profile generation for semiconductor device structures in a virtual fabrication environment. More particularly, embodiments enable the modeling of complicated PR profiles that occur during fabrication of semiconductor device structures such as advanced DRAM structures using contour masks to describe the PR profile of a structure at the top and bottom and optionally one or more locations in between. The contour masks are used to create a 2D loading map which is used by an etch process during virtual fabrication to quickly generate a 3D PR profile.

In one embodiment, a computing device-implemented method for performing 3D photoresist profile generation in a virtual fabrication environment includes receiving in a virtual fabrication environment a top contour mask that describes a photoresist profile at a top of a semiconductor device structure being fabricated and a bottom contour mask that describes a photoresist profile at a bottom of a semiconductor device structure being fabricated. The method also includes creating a loading map using a subset of density information extracted from the top contour mask and the bottom contour mask and performing an etch operation using the loading map to generate a 3D photoresist profile for the semiconductor device structure. The result of the etch operation is output.

In another embodiment, a system for performing 3D photoresist profile generation includes at least one computing device equipped with one or more processors that is configured to generate a virtual fabrication environment that includes a 3D photoresist profile generation module. The 3D photoresist profile generation module when executing receiving a top contour mask that describes a photoresist profile at a top of a semiconductor device structure being fabricated and a bottom contour mask that describes a photoresist profile at a bottom of a semiconductor device structure being fabricated. The 3D photoresist profile generation module when executing also includes creating a loading map using a subset of density information extracted from the top contour mask and the bottom contour mask and performing an etch operation using the loading map to generate a 3D photoresist profile for the semiconductor device structure. The system also includes a display surface for displaying an output of the etch operation.

### BRIEF DESCRIPTION OF THE DRAWINGS

The accompanying drawings, which are incorporated in and constitute a part of this specification, illustrate one or more embodiments of the invention and, together with the description, help to explain the invention. In the drawings:

FIG. 1 depicts an exemplary virtual fabrication environment suitable for practicing an embodiment of the present invention;

FIG. 2 depicts an exemplary 3D viewer provided by the virtual fabrication environment;

FIGS. 3A-3B depict an exemplary semiconductor device structure being fabricated with a tapered profile and corresponding grid density maps;

FIG. 4 depicts the application of a speed parameter for extracting a subset of density information from a contour mask in an exemplary embodiment;

FIG. 5 depicts the combining of density information extracted from a top and bottom mask for a semiconductor device structure into an on-grid data map in an exemplary embodiment;

FIG. 6 depicts the extraction of edge data from a top and bottom mask for a semiconductor device structure into an off-grid data map in an exemplary embodiment;

FIG. 7 depicts the combination of the on-grid data map and the off-grid data map into a loading list in an exemplary embodiment;

FIG. 8 depicts the use of a loading list to perform grid interpolation to generate a loading map in an exemplary embodiment;

FIG. 9 depicts a user interface for selecting parameters to perform 3D PR profile generation in an exemplary embodiment;

FIG. 10 depicts the use of the generated loading map to perform an etch operation to generate a 3D photoresist profile in an exemplary embodiment;

FIG. 11A depicts the use of at least one additional mask to perform 3D PR profile generation in an exemplary embodiment;

FIG. 11B depicts an exemplary 2D loading map and exploded view of the map produced using data from a middle mask;

FIG. 12 depicts a user interface for selecting parameters related to the use of at least one additional mask to perform 3D PR profile generation in an exemplary embodiment;

FIG. 13 depicts the effects of interpolating extra edge data for square cornered polygons on a mask;

FIG. 14 depicts a user interface for selecting a polarity parameter to perform 3D PR profile generation in an exemplary embodiment; and

FIG. 15 depicts a sequence of steps performed in the virtual fabrication environment to perform 3D photoresist profile generation in an exemplary embodiment.

### DETAILED DESCRIPTION

With semiconductor devices scaling to the lowest achievable limits, the ability to exercise photoresist profile control during fabrication has taken on increasing importance. Without accurate PR profiles, the ability to accurately model device fabrication in a virtual fabrication environment becomes a significant challenge. As the structures being fabricated have become increasingly smaller, the process sequences used to produce the structures have generated increasingly complicated PR profiles. These PR profiles are of critical importance to ensure the accurate Si structure build during virtual fabrication that is needed to optimize the fabrication processes that subsequently takes place in the physical fab. Embodiments of the present invention provide a virtual fabrication environment that enables the 3D PR profile generation necessary to accurately model today's increasingly complicated fabrication processes. However, prior to discussing the 3D photoresist profile generation provided by embodiments in greater detail, an exemplary 3D virtual fabrication environment which may be utilized to practice the embodiments is first described.

### Exemplary Virtual Fabrication Environment

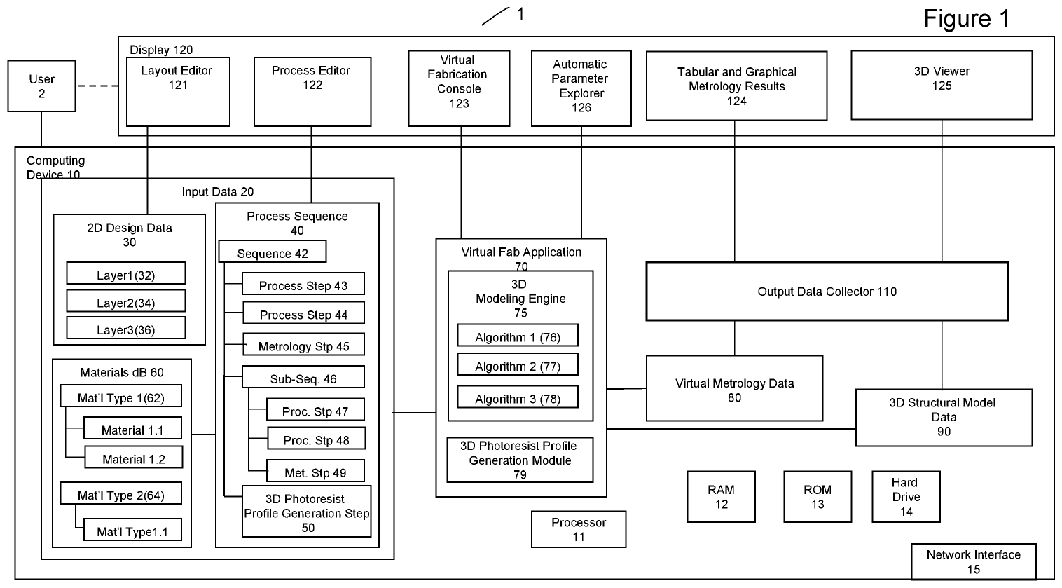

FIG. 1 depicts an exemplary virtual fabrication environment 1 suitable for practicing an embodiment of the present invention. Virtual fabrication environment 1 includes a computing device 10 accessed by a user 2. Computing device 10 is in communication with a display 120. Display 120 may be a display screen that is part of computing device 10 or may be a separate display device or display surface in communication with computing device 10. Computing device 10 may be a PC, laptop computer, tablet computing device, server, mobile computing device or some other type of computing device equipped with a processor 11 and able to support the operations of 3D modeling engine 75 (described further below). The processor may have one or more cores. The computing device 10 may also include volatile and non-volatile storage such as, but not limited to, Random Access Memory (RAM) 12, Read Only Memory (ROM) 13 and hard drive 14. Computing device 10 may also be equipped with a network interface 15 so as to enable communication with other computing devices.

Computing device 10 may store and execute virtual fabrication application 70 including 3D modeling engine 75. 3D modeling engine 75 may include one or more algorithms such as algorithm 1 (76), algorithm 2 (77), and algorithm 3 (78) used in virtually fabricating semiconductor device structures. Virtual fabrication application 70 may also include 3D PR profile generation module 79 containing executable instructions for 3D PR profile generation modeling operations. 3D modeling engine 75 may accept input data 20 in order to perform virtual fabrication “runs” that produce semiconductor device structural model data 90. Virtual fabrication application 70 and 3D modeling engine 75 may generate a number of user interfaces and views used to create and display the results of virtual fabrication runs. For example, virtual fabrication application 70 and 3D modeling engine 75 may display layout editor 121, process editor 122 and virtual fabrication console 123 used to create virtual fabrication runs. Virtual fabrication application 70 and 3D modeling engine 75 may also display a tabular and graphical metrology results view 124 and 3D view 125 for respectively displaying results of virtual fabrication runs and 3D structural models generated by the 3D modeling engine 75 during virtual fabrication of semiconductor device structures.

Input data 20 includes both 2D design data 30 and process sequence 40. Process sequence 40 may be composed of multiple process steps 43, 44, 47, 48 and 49. Process sequence 40 may also include one or more virtual metrology measurement process steps 45. Process sequence 40 may further include one or more subsequences which include one or more of the process steps or virtual metrology measurement process steps. 2D design data 30 includes of one or more layers such as layer 1 (32), layer 2 (34) and layer 3 (36), typically provided in an industry-standard layout format such as GDS II (Graphical Design System version 2) or OASIS (Open Artwork System Interchange Standard).

Input data 20 may also include a materials database 60 including records of material types such as material type 1 (62) and material type 2 (64) and specific materials for each material type. Many of the process steps in a process sequence may refer to one or more materials in the materials database. Each material has a name and some attributes such as a rendering color. The materials database may be stored in a separate data structure. The materials database may have hierarchy, where materials may be grouped by types and sub-types. Individual steps in the process sequence may refer to an individual material or a parent material type. The hierarchy in the materials database enables a process sequence referencing the materials database to be modified more easily. For example, in virtual fabrication of a semiconductor device structure, multiple types of oxide material may be added to the structural model during the course of a process sequence. After a particular oxide is added, subsequent steps may alter that material. If there is no hierarchy in the materials database and a step that adds a new type of oxide material is inserted in an existing process sequence, all subsequent steps that may affect oxide materials must also be modified to include the new type of oxide material. With a materials database that supports hierarchy, steps that operate on a certain class of materials such as oxides may refer only to the parent type rather than a list of materials of the same type. Then, if a step that adds a new type of oxide material is inserted in a process sequence, there is no need to modify subsequent steps that refer only to the oxide parent type. Thus hierarchical materials make the process sequence more resilient to modifications. A further benefit of hierarchical materials is that stock process steps and sequences that refer only to parent material types can be created and re-used.

3D Modeling Engine 75 uses input data 20 to perform the sequence of operations/steps specified by process sequence 40. As explained further below, process sequence 40 may include one or more virtual metrology steps 45, 49 that indicate a point in the process sequence during a virtual fabrication run at which a measurement of a structural component should be taken. The measurement may be taken using a locator shape previously added to a layer in the 2D design data 30. In an alternative approach, the measurement location may be specified by alternate means such as (x, y) coordinates in the 2D design data or some other means of specifying a location in the 2D design data 30 instead of through the use of a locator shape. Process sequence may also include one or more 3D PR profile generation steps 50 that indicate a point in the process sequence during a virtual fabrication run at which a 3D PR profile generation operation should be performed as described further herein. The performance of the process sequence 40 during a virtual fabrication run generates virtual metrology data 80 and 3D structural model data 90. 3D structural model data 90 may be used to generate a 3D view of the structural model of the semiconductor device structure which may be displayed in the 3D viewer 125. Virtual metrology data 80 may be processed and presented to a user 2 in the tabular and graphical metrology results view 124.

The virtual fabrication environment may include a virtual fabrication console used to set up a virtual fabrication run. The virtual fabrication console 123 allows the user to specify a process sequence and the layout (2D design data) for the semiconductor device structure that is being virtually fabricated. It should be appreciated however that the virtual fabrication console can also be a text-based scripting console that provides the user with a means of entering scripting commands that specify the required input and initiate building of a structural model, or building a set of structural models corresponding to a range of parameter values for specific steps in the process sequence. The latter case is considered a virtual experiment (discussed further below).

The virtual fabrication environment may also include a layout editor. The layout editor 121 displays the 2D design layout specified by the user in the virtual fabrication console 123. In the layout editor, color may be used to depict different layers in the design data. The areas enclosed by shapes or polygons on each layer represent regions where a photoresist coating on a wafer may be either exposed to light or protected from light during a photolithography step in the integrated process flow. The shapes on one or more layers may be combined (booleaned) to form a mask that is used in a photolithography step. The layout editor 121 provides a means of inserting, deleting and modifying a polygon on any layer, and of inserting, deleting or modifying layers within the 2D design data. A layer can be inserted for the sole purpose of containing shapes or polygons that indicate the locations of virtual metrology measurements. For example, rectangular shapes may be added to an inserted layer (indicated by a different color) to mark the locations of virtual metrology measurements. As noted above, other approaches to specifying the locations for the virtual metrology measurements besides the use of locator shapes may also be used. The design data is used in combination with the process data and materials database to build a 3D structural model.

Inserted layers in the design data displayed in the layout editor 121 may include inserted locator shapes. For example, a locator shape may be a rectangle, the longer sides of which indicate the direction of the measurement in the 3D structural model. For example, a first locator shape may mark a double patterning mandrel for a virtual metrology measurement, a second locator shape may mark a gate stack for a virtual metrology measurement and a third locator shape may mark a transistor source or drain contact for a virtual metrology measurement.

As noted, the virtual fabrication environment may also include process editor 122. The user may define a process sequence in the process editor. The process sequence is an ordered list of process steps conducted in order to virtually fabricate the user's selected structure. The process editor may be a text editor, such that each line or group of lines corresponds to a process step, or a specialized graphical user interface. The process sequence may be hierarchical, meaning process steps may be grouped into sub-sequences and sub-sequences of sub-sequences, etc. Generally, each step in the process sequence corresponds to an actual step in the fab. For instance, a sub-sequence for a reactive ion etch operation might include the steps of spinning on photo resist, patterning the resist, and performing the etch operation. The user specifies parameters for each step or sub-step that are appropriate to the operation type. Some of the parameters are references to materials in the materials database and layers in the 2D design data. For example, the parameters for a deposit operation primitive are the material being deposited, the nominal thickness of the deposit and the anisotropy or ratio of growth in the lateral direction versus the vertical direction. This deposit operation primitive can be used to model processes such as chemical vapor deposition (CVD). Similarly, the parameters for an etch operation primitive are a mask name (from the design data), a list of materials affected by the operation, and the anisotropy.

There may be hundreds of steps in the process sequence and the process sequence may include sub-sequences. For example, a process sequence may include a subsequence made up of multiple process steps. The process steps may be selected from a library of available process steps. For a selected step, the process editor may enable a user to specify all required parameters. For example, a user may be able to select a material from a list of materials in the material database and specify a process parameter for the material's use in the process step.

One or more steps in the process sequence may be virtual metrology steps inserted by a user. For example, the insertion of step “Measure CD” (414), where CD denotes a critical dimension, in the process sequence would cause a virtual metrology measurement to be taken at that point in the virtual fabrication run using one or more locator shapes that had been previously inserted on one or more layers in the 2D design data. By inserting the virtual metrology steps directly in the fabrication sequence, virtual metrology measurements may be taken at critical points of interest during the fabrication process. As the many steps in the virtual fabrication interact in the creation of the final structure, the ability to determine geometric properties of a structure, such as cross-section dimensions and surface area, at different points in the integrated process flow is of great interest to the process developer and structure designer.

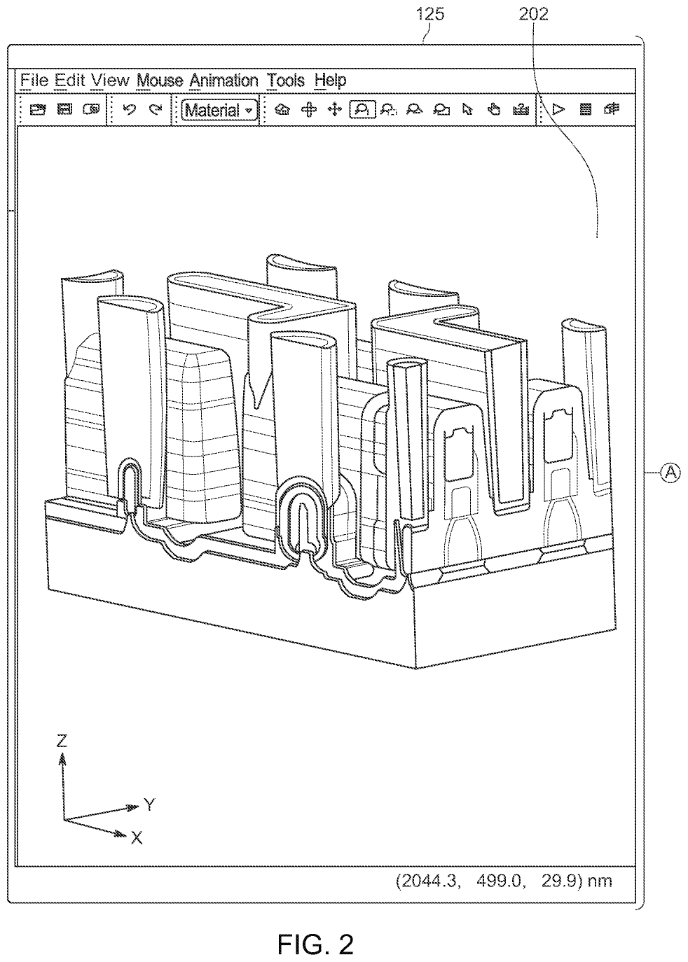

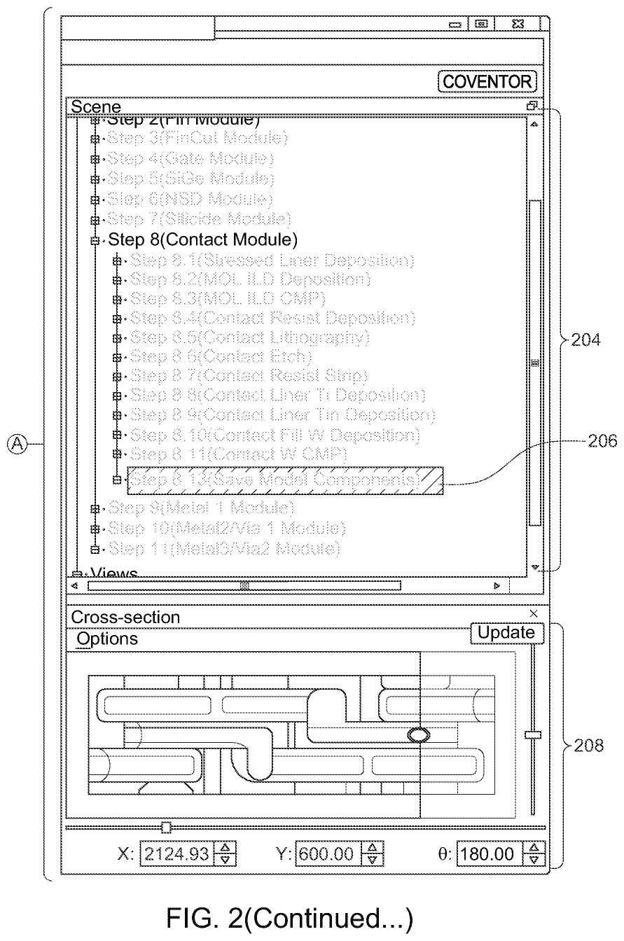

FIG. 2 depicts an exemplary 3D viewer 125 provided by the virtual fabrication environment. The 3D viewer 125 may include a 3D view canvas 202 for displaying 3D models generated by the 3D modeling engine 75. The 3D viewer 125 may display saved states 204 in the process sequence and allow a particular state to be selected 206 and appear in the 3D view canvas. 3D Viewer 125 may provide functionality such as zoom in/out, rotation, translation, cross section, etc. Optionally, the user may activate a cross section view in the 3D view canvas 202 and manipulate the location of the cross section using a miniature top view 208.

While building a single structural model can be valuable, there is increased value in virtual fabrication that builds a large number of models. The virtual fabrication environment enables a user to create and run a virtual experiment/Design of Experiment (DOE). In a virtual experiment, a range of values of process parameters can be explored. A virtual experiment may be set up by specifying a set of parameter values to be applied to individual processes (rather than a single value per parameter) in the full process sequence. A single process sequence or multiple process sequences can be specified this way. The 3D modeling engine 75, executing in virtual experiment mode, then builds multiple models spanning the process parameter set, all the while utilizing the virtual metrology measurement operations described above to extract metrology measurement data for each variation. This capability may be used to mimic two fundamental types of experiments that are typically performed in the physical fab environment. Firstly, fabrication processes vary naturally in a stochastic (non-deterministic) fashion. The virtual fabrication environment described herein, uses a fundamentally deterministic approach for each virtual fabrication run that nevertheless can predict non-deterministic results by conducting multiple runs. The virtual experiment mode allows the virtual fabrication environment to model through the entire statistical range of variation for each process parameter, and the combination of variations in many/all process parameters. Secondly, experiments run in the physical fab may specify a set of parameters to be intentionally varied when fabricating different wafers. The virtual experiment mode of the present invention enables the virtual fabrication environment to mimic this type of experiment as well, by performing multiple virtual fabrication runs on the specific variations of a parameter set.

Each process in the fabrication sequence has its own inherent variation. To understand the effect of all the aggregated process variations in a complex flow is quite difficult, especially when factoring in the statistical probabilities of the combinations of variations. Once a virtual experiment is created, the process sequence is essentially described by the combination of numerical process parameters included in the process description. Each of these parameters can be characterized by its total variation (in terms of standard deviation or sigma values), and therefore by multiple points on a Gaussian distribution or other appropriate probability distribution. If the virtual experiment is designed and executed to examine all of the combinations of the process variations (multiple points on each Gaussian, for example the ±3 sigma, ±2 sigma, ±1 sigma, and nominal values of each parameter), then the resulting graphical and numerical outputs from virtual metrology steps in the sequence cover the total variation space of the technology. Even though each case in this experimental study is modeled deterministically by the virtual fabrication system, the aggregation of the virtual metrology results contains a statistical distribution. Simple statistical analysis, such as Root Sum Squares (RSS) calculation of the statistically uncorrelated parameters, can be used to attribute a total variation metric to each case of the experiment. Then, all of the virtual metrology output, both numerical and graphical, can be analyzed relative to the total variation metric.

In typical trial-and-error experimental practice in a physical fab, a structural measurement resulting from the nominal process is targeted, and process variations are accounted for by specifying an overly large (conservative) margin for the total variation in the structural measurement (total structural margin) which must be anticipated in subsequent processes. In contrast, a virtual experiment can be designed to provide quantitative predictions of the total variation envelope for a structural measurement at any point in the integrated process flow. The total variation envelope, rather than the nominal value, of the structural measurement may then become the development target. This approach can ensure acceptable total structural margin throughout the integrated process flow, without sacrificing critical structural design goals. This approach, of targeting total variation may result in a nominal intermediate or final structure that is less optimal (or less aesthetically pleasing) than the nominal structure that would have been produced by targeting the nominal process. However, this sub-optimal nominal process is not critical, since the envelope of total process variation has been accounted for and is more important in determining the robustness and yield of the integrated process flow. This approach is a shift in semiconductor technology development, from an emphasis on the nominal process to an emphasis on the envelope of total process variation.

To set up and perform a virtual experiment generating virtual metrology measurement data for multiple semiconductor device structural models a user may select a process sequence (which may have been previously calibrated to make the results more structurally predictive and identify/create 2D design data. The user may select process parameter variations to analyze and/or design parameter variations to analyze. The user may insert one or more virtual metrology steps in the process sequence and add measurement locator shapes to the 2D design data. The user may set up the virtual experiment with the aid of a specialized user interface, an automatic parameter explorer 126. The automatic parameter explorer may display, and allow the user to vary, the process parameters to be varied and the list of 3D models to be built with their corresponding different parameter values. The parameter ranges for a virtual experiment can be specified in a tabular format. The 3D modeling engine 75 builds the 3D models and exports the virtual metrology measurement data for review. A virtual experiment mode may provide output data handling from all virtual measurement/metrology operations. The output data from the virtual metrology measurements may be parsed and assembled into a useful form.

With this parsing and assembling, subsequent quantitative and statistical analysis can be conducted. A separate output data collector module 110 may be used to collect 3D model data and virtual metrology measurement results from the sequence of virtual fabrication runs that comprise the virtual experiment and present them in graphical and tabular formats. For example, a tabular-formatted display of virtual metrology data generated by a virtual experiment may be generated. In the tabular formatted display, the virtual metrology data collected during the virtual experiment and the list of virtual fabrication runs may be displayed.

Alternatively or in addition an exemplary 2D X-Y graphical plot display of virtual metrology data generated by a virtual experiment may be displayed. For example, the total variation in shallow trench isolation (STI) step height due to varying 3 parameters in preceding steps of the process sequence may be shown with an indicator representing each virtual fabrication run. The variation envelope may also be displayed as may a depicted conclusion. The virtual experiment results can also be displayed in multi-dimensional graphic formats.

Once the results of the virtual experiment have been assembled, the user can review 3D models that have been generated in 3D viewer 125 and review the virtual metrology measurement data and metrics presented for each virtual fabrication run. Depending on the purpose of the virtual experiment, the user can analyze the output from the 3D modeling engine for purposes of developing a process sequence that achieves a desired nominal structural model, for further calibrating process step input parameters, or for optimizing a process sequence to achieve a desired process window.

The 3D modeling engine's 75 task of constructing multiple structural models for a range of parameter values (comprising a virtual experiment) is very compute intensive and therefore could require a very long time (many days or weeks) if performed on a single computing device. To provide the intended value of virtual fabrication, model building for a virtual experiment must occur many times faster than a physical experiment. Achieving this goal requires exploiting any and all opportunities for parallelism. The 3D modeling engine 75 of the present invention uses multiple cores and/or processors to perform individual modeling steps. In addition, the structural models for different parameter values in a set are completely independent and can therefore be built in parallel using multiple cores, multiple processors, or multiple systems.

3D modeling engine 75 may represent the underlying structural model using a voxel-based implicit geometry representation. Voxels are essentially 3D pixels. Each voxel is a cube of the same size, and may contain one or more materials, or no materials. An implicit geometry representation is one in which the interface between materials in the 3D structural model are defined without an explicit representation of the (x,y,z) coordinate locations of that interface. Many of the operations performed by the 3D modeling engine are voxel modeling operations. Modeling operations based on a digital voxel representation are far more robust than the corresponding operations in a conventional analog solid modeling kernel (e.g. a NURBS-based solid modeling kernel). Such solid modeling kernels generally rely on a large number of heuristic rules to deal with various geometric situations, and modeling operations may fail when the heuristic rules do not properly anticipate a situation. Aspects of semiconductor structural modeling that cause problems for NURBS-based solid modeling kernels include the very thin layers produced by deposition processes and propagation of etch fronts that results in merging faces and/or fragmentation of geometry.

Some simulation tools require a volume mesh to be generated from some form of explicit boundary representation and previous solutions exist for creating a volume mesh of B-rep geometry or from surface meshes. Such volume meshes for finite-element or finite-volume simulation techniques will preserve the location of the interface between materials to a high level of accuracy. Such a volume mesh is called a boundary-conforming mesh or simply a conformal mesh. A key feature of such a mesh is that no element crosses the boundary between materials. In other words, for a volume mesh of tetrahedral elements, then each element is wholly within one material and thus no tetrahedron contains more than one material. However, neither B-rep and similar solid modeling kernels, nor surface mesh representations are optimal for virtual fabrication. Solid modeling kernels generally rely on a large number of heuristic rules to deal with various geometric situations, and modeling operations may fail when the heuristic rules do not properly anticipate a situation. Geometry representations that instead represent the boundaries implicitly do not suffer from these problems. A virtual fabrication system that uses an implicit representation exclusively thus has significant advantages, even if it may not represent the interfaces as accurately.

Geometric data represented with voxels implicitly represents the interface between materials. For example, A B-rep representation may represent the circle as the equation of a circle with radius R with a first material inside the circle and a second material outside. In contrast, a voxel representation of the circle is an array of cubes where each cube stores the material identification numbers within it, and the relative amounts of each material. Since the circle cuts through the voxels along its path, voxels on the boundary of the circle are partially filled with each material. Partially filled voxels indicate that the boundary crosses through that voxel, but does not indicate where and with what orientation. The fill fractions of a boundary voxel and others in its neighborhood may be used to determine the boundary explicitly.

Material properties at a location within the geometry may be approximated using the properties of the majority material within each voxel. For instance, in an operation to determine electrical resistance, if a boundary voxel is more than 50% of a material, then the bulk resistivity of that material is used for all values of x within that voxel, and similarly voxels of 50% or more of a different material use the bulk resistivity of that different material. This is equivalent to filling those voxels full of the majority material. This approach incurs what is called ‘staircasing’ error in the solution over methods that explicitly know the boundary location, and thus know precisely the material at each location, x. One method to compensate for staircasing error is to decrease the size of each voxel when performing the virtual fabrication of the 3D model and thus reduce the volume of boundary voxels. The volume taken up by boundary voxels is much less with the smaller voxel size and thus the error would be less. It should be noted however that decreasing the voxel size greatly increases both the virtual fabrication computation time as well as the simulation time which may lead to unacceptable results in some circumstances.

### 3D Photoresist Profile Generation

3D PR profile simulation is important for accurate semiconductor device structure builds in virtual fabrication environments. Unfortunately many conventional methods either only support 2D simulation in OPC-related tools or need to perform extensive 2D meshing at different elevations of a structure and such methods are very complicated and time consuming. Embodiments of the present invention create a 2D loading map from contour masks that describe the PR profile at the top and bottom of a semiconductor device structure (and optionally one or more additional contour masks at depths in-between) and use the loading map during an etching operation to generate an accurate 3D profile for the structure.

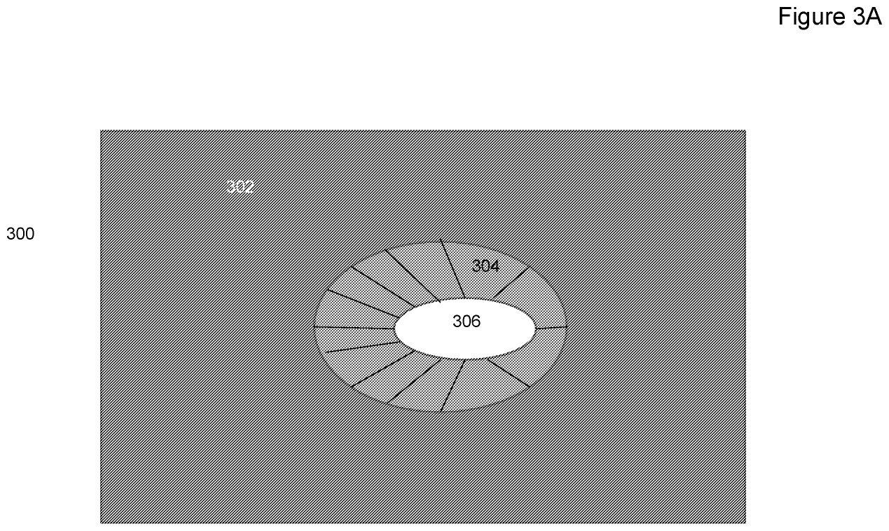

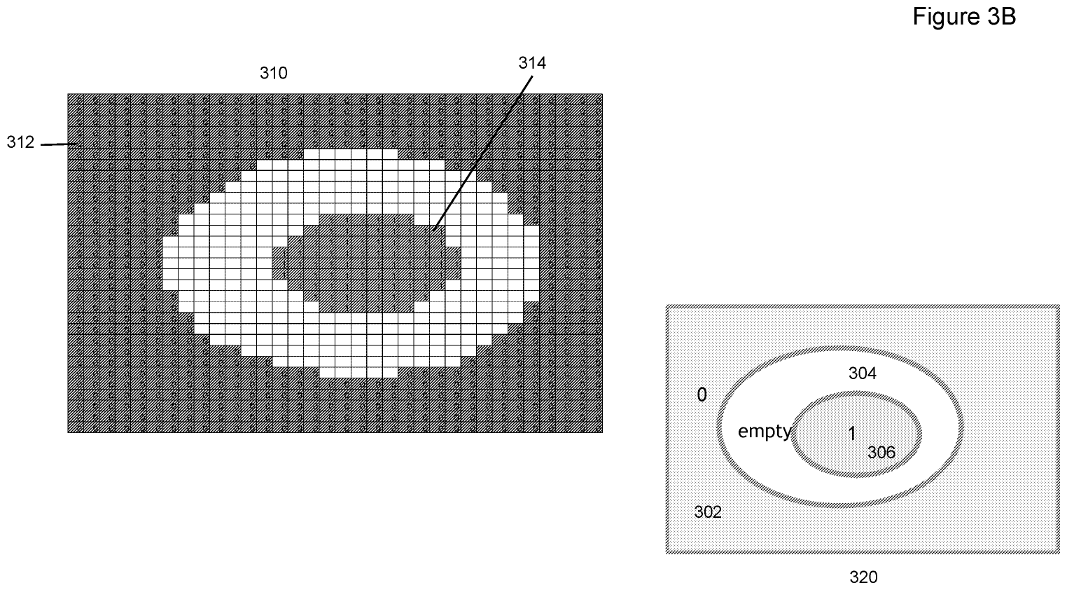

FIGS. 3A-3B depict an exemplary semiconductor device structure being fabricated with a tapered PR profile and associated density maps. As shown in FIG. 3A, an exemplary semiconductor device structure 300 may have a top surface 302 and a bottom surface 306. A tapered opening 304 may extend from the top surface 302 to the bottom surface 306. Represented as a density map grid 310 as shown in FIG. 3B, the top surface 302 may be indicated in each grid location to have a depth of 0 (312) while the bottom surface 306 may be indicated in each grid location to have a depth of 1 (314). The tapered area 304 represented in the density map grid may initially be empty of data as visually depicted in grid map 320 with interpolation methods being later used to supply the missing data from the extracted data and generate a loading map.

As described further herein, embodiments of the present invention use top and bottom 2D contour masks describing the PR profile of a semiconductor device structure being fabricated, and optionally one or more additional contour masks corresponding to depths between the top and bottom of the structure, to generate a 2D loading map. The contour masks may be obtained in a number of different ways. For example, the contour masks be obtained from existing OPC tools or lithography simulation tools. Once generated, the 2D loading map is used during an etch operation in the process sequence to generate a 3D PR profile for the semiconductor device structure. The loading map scales the nominal etch process parameters to modify process behavior such as the etch rate. It will be appreciated that the loading map is a 2-D function in x and y, while virtual fabrication behavioral parameters are typically evaluated at points in 3-D space on the surface of the device structure being modeled. Embodiments evaluate 3-D behavioral parameter value at any point (x.y.z) using the loading map value at position (x,y).

While the density map grid 310 of the exemplary semiconductor device structure shown in FIG. 3B could be used to generate a loading map, the generation and application of such a loading map would take too long to be practical for simulation purposes (for example, in one experiment using such a map the run time was 10 hours for a 1 um×1 um area with a resolution=1 nm). Accordingly, embodiments of the present invention utilize a subset of information extracted from each of the contour masks to generate corresponding density maps. More particularly, embodiments control the amount of information extracted from the contour masks through the use of a parameter which indicates how far apart the locations on the contour masks are that are checked for data. As the value of this parameter controls the speed of generating the 3D PR profile, the parameter is referred to herein as a “speed” parameter.

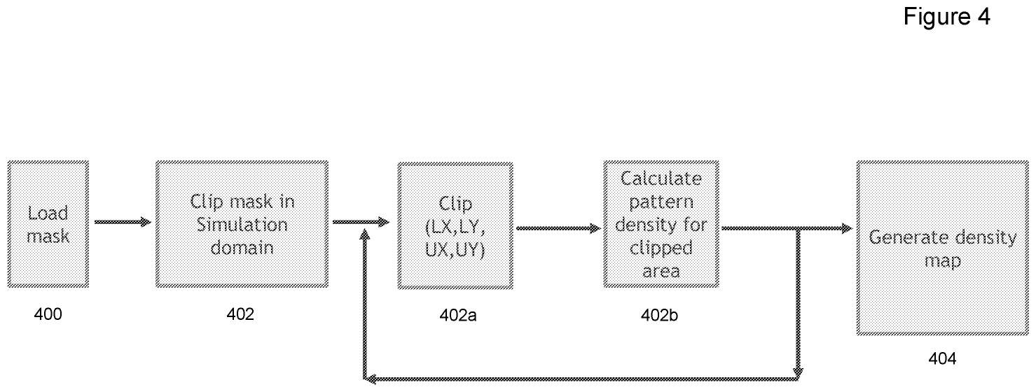

In one embodiment, a top contour mask and a bottom contour mask are used as input to the 3D PR profile generation module to create a 2D loading map. More particularly, a subset of pattern density information from the masks is extracted and used to create a 2D loading map. FIG. 4 depicts the use of a speed parameter for extracting a subset of density information from a contour mask in an exemplary embodiment. The contour mask data is first loaded into the virtual fabrication environment (step 400). The mask is then iteratively clipped in different locations (step 402) to extract density data at each location. More particularly, at each location (step 402a), the pattern density for the clipped area is calculated (step 402b) and the process then loops to the next location a distance away based upon the value of the speed parameter (which equates to a specified number of map grids away). To calculate the pattern density at particular x,y location, one square mask is clipped from the large mask (lower left coordinate LX.LY, upper right coordinate UX,UY, with the size of the clipped square matching the voxel size in the xy plane). A mask function is used to extract the pattern area in the small square mask. This extracted area divided by the whole (small) square area represents the pattern density at this x.y location. The result when the end of the mask data is reached is a density map 404 for which, in one embodiment, data may be stored in the form of a numpy array. An exemplary density map grid produced by the use of a speed parameter contains a subset of information extracted from the contour mask.

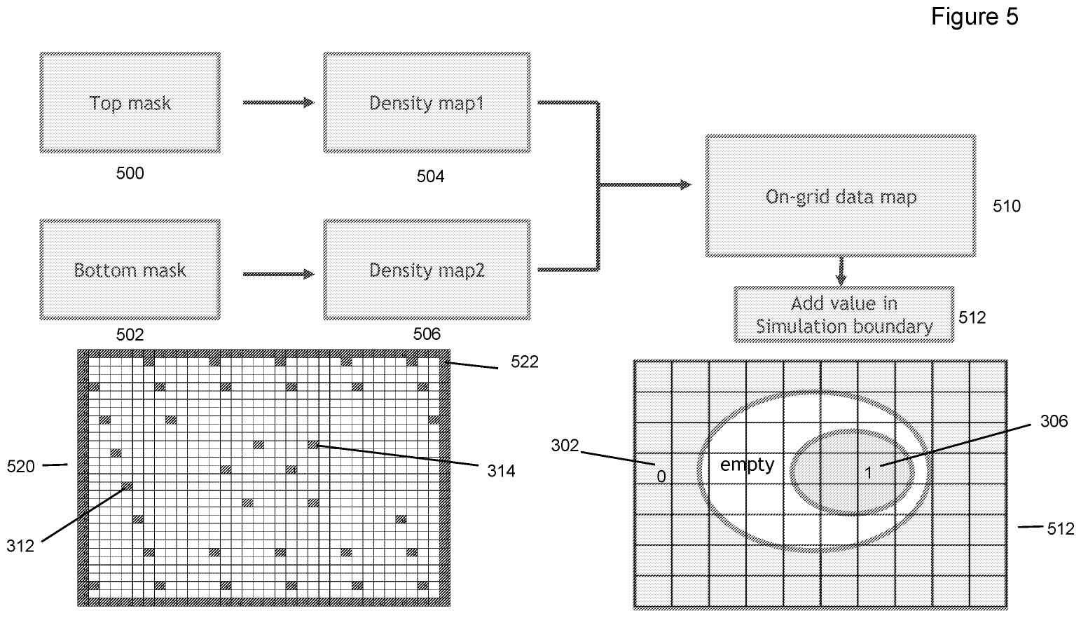

FIG. 5 depicts the combining of density information extracted from a top and bottom contour mask for a semiconductor device structure into an on-grid data map in an exemplary embodiment. As shown, a top contour mask and a bottom contour mask are received in the virtual fabrication environment (steps 502,504) and used to respectively generate top and bottom density maps (steps 506,508) in the manner discussed above with respect to FIG. 4. The information may then be combined into a combined on-grid density map (step 510). Additional values 522 are added to the simulation boundary (step 512) in the density map grid. The combined density map grid 520 is still missing data (corresponding to the tapered portion 304 of the semiconductor device structure between the mask levels) and interpolation is used to supply the missing data and generate a loading map. Because only a subset of data from the top and bottom contour masks is extracted the simulation run-times using the generated loading map is much quicker than the approach used in FIG. 3B (for example, in one experiment using a map constructed with a speed parameter the run time was 1 minute for a 1 um×1 um area with a resolution=1 nm).

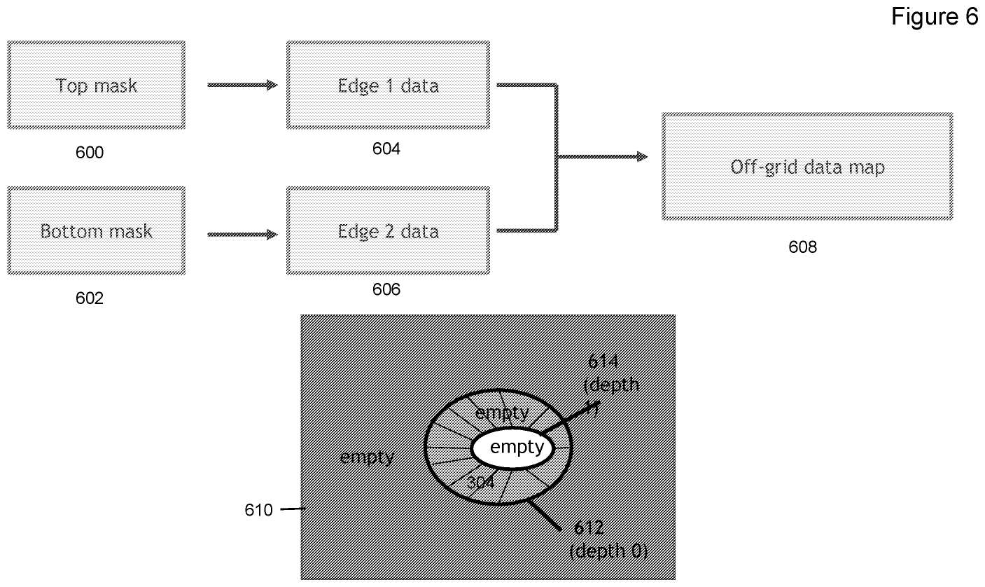

While the loading map built using a speed parameter to extract a subset of data from the contour masks as discussed in FIG. 5 represents a marked speed improvement over simulations utilizing a loading map built using all of the data, the resulting simulation still suffers from the problem that the PR profile edge may be considered too rough for optimal modeling. To address this, in an embodiment, edge data is also extracted from the contour masks to integrate off-grid data into the loading map. For example, FIG. 6 depicts the extraction of edge data from a top and bottom contour mask for a semiconductor device structure into an off-grid data map in an exemplary embodiment. More particularly, as shown, a top contour mask and a bottom contour mask are imported into the virtual fabrication environment (step 600, 602). Edge data is respectively extracted from each mask (steps 604,606) by looping between vertices of the polygon (note: ellipses and curved shapes may be represented in the virtual fabrication environment using many-sided polygons that approximate the shapes). The top and bottom edge data is combined into an off-grid data map (step 608). This edge data is non-integer data not corresponding to a grid line. As shown in map 610 the tapered area 304 of the semiconductor device structure being fabricated includes a top elliptical edge 612 on the top surface 302 (with a depth value of 0) and a bottom elliptical edge 614 on the bottom surface 306 (with a depth value of 1).

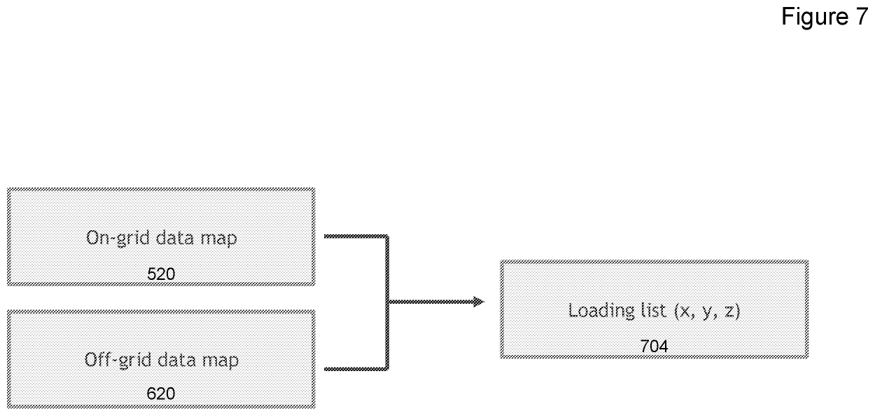

Once the off-grid-data map has been created to capture edge data, the off-grid data map may be combined with the on-grid data map to provide a more complete map that can be used to interpolate missing data. FIG. 7 depicts the combination of the on-grid data map and the off-grid data map in an exemplary embodiment. For example, an on-grid data map 520 may be combined with an off-grid data map 610 to generate a loading list 704 (x,y,z). Because the loading list includes data from both maps it is not fully on-grid.

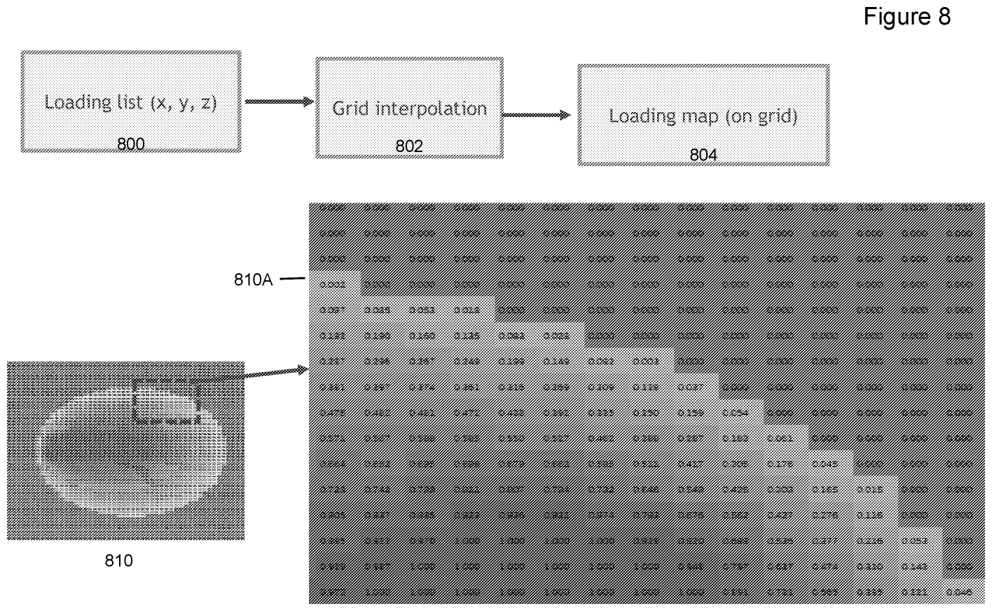

The loading list 704 may be provided as input data to the 3D PR profile generation module 79 to generate a 2D loading map. FIG. 8 depicts the use of a loading list to perform grid interpolation to generate a loading map in an exemplary embodiment. For example, the loading list 704 may be provided as input data (step 802) to an interpolation method that interpolates data (step 804) for the missing portions of the semiconductor device structure (e.g.: tapered area 304) based upon the extracted on-grid and off-grid data. A 2D loading map 810 for an etch operation is generated (step 806) based on both the extracted and interpolated data. The loading map values are used to alter the etch rate of an etching operation used to fabricate the semiconductor device structure so as to quickly generate an accurate 3D PR profile.

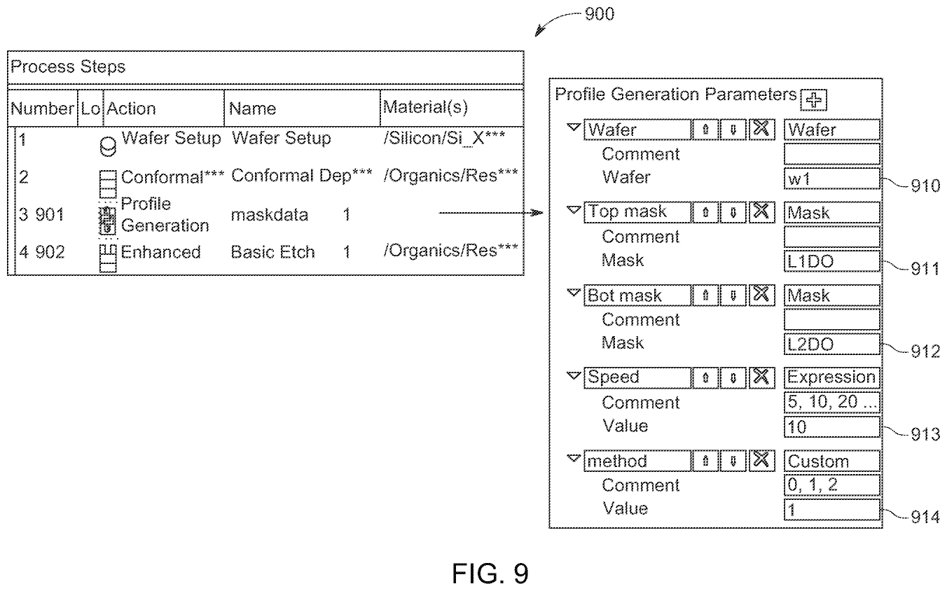

In one embodiment, the virtual fabrication environment may provide a user interface to receive user-specified parameters for 3D PR profile generation. FIG. 9 depicts a user interface for selecting parameters to perform 3D PR profile generation in an exemplary embodiment. More particularly, user interface 900 enables a user to add a 3D profile generation step 901 to the process sequence prior to the etch step 902. For example, exemplary profile generation parameters selected by a user may include wafer 910, top mask 911, bottom mask 912 and a speed parameter 913 which controls the number of on-grid density calculated points. In one embodiment, the user may also select the type of interpolation method 914 used to create the 2D loading map. It should be appreciated that in some embodiments, some or all of the parameters may instead be automatically supplied by the virtual fabrication environment and that other parameters for 3D PR profile generation not specifically discussed herein may also be supplied by a user via the user interface without departing from the scope of the present invention.

A number of different interpolation methods may be used to generate the 2D loading map from the loading list such as, but not limited to, linear interpolation, cubic interpolation or a Clough Tocher 2D interpolation method. As non-limiting examples, a Clough Tocher 2D interpolation method may be represented as:

$$\begin{matrix}XN = np . linspace ( min ( X ) , max ( X ) , m ) \\ YN = np . linspace ( min ( Y ) , max ( Y ) , n ) \\ XN , YN = np . meshgrid ( XN , YN ) \# 2 D grid for interpolation \\ Interp = CloughTocher 2 DInterpolator ( list ( zip ( X , Y ) ) , Z ) \\ ZN = interp ( XN , YN )\end{matrix}$$

while a linear interpolation method may be represented as:

$$\begin{matrix}XN , YN = np . mgrid [ 0 : max ( X ) + 1 : 1 , 0 : max ( Y ) + 1 : 1 ] \\ ZN = griddata ( list ( zip ( X , Y ) ) , Z ( XN , YN ) , method = ‘ linear ’ )\end{matrix}$$

and a cubic interpolation method may be represented as:

$$\begin{matrix}XN , YN = np . mgrid [ 0 : max ( X ) + 1 : 1 , 0 : max ( Y ) + 1 : 1 ] \\ ZN = griddata ( list ( zip ( X , Y ) ) , Z ( XN , YN ) , method = ‘ cubic ’ )\end{matrix}$$

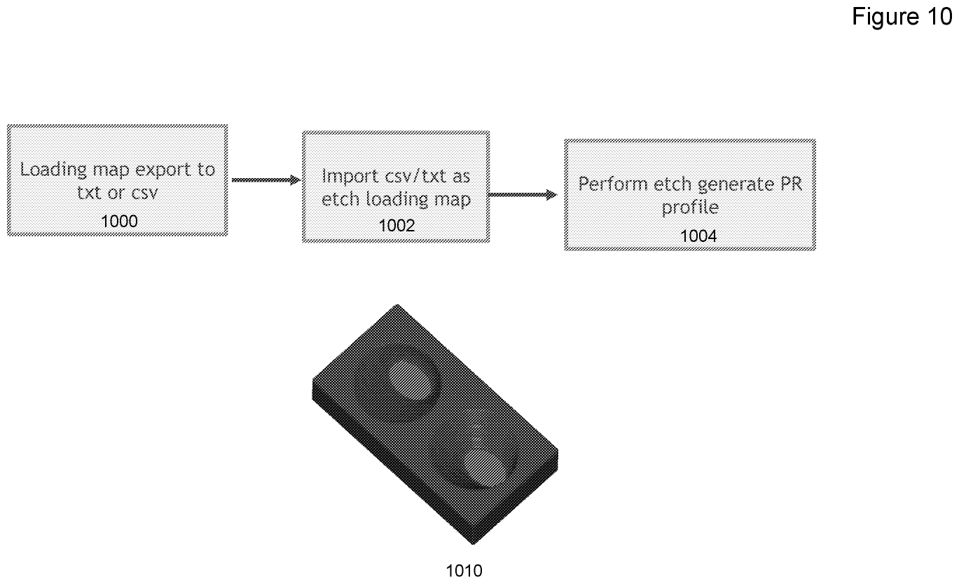

Once the 2D loading map has been generated, the loading map is used during an etch operation in the fabrication sequence. FIG. 10 depicts the use of the generated loading map to perform an etch operation to generate a 3D photoresist profile in an exemplary embodiment. The exemplary sequence begins with the 2D loading map being exported to a text or comma separated file (i.e., .txt or .csv file) (step 1000). Once converted the .txt or .csv file is imported into the virtual fabrication environment (step 1002) and used to control the etch operation in the fabrication sequence by multiplying the etch rate at different locations by the etch depth as reflected in the loading map to generate a 3D PR profile (step 1004) for the semiconductor device structure being fabricated. An exemplary structure 1010 depicts the result of the etch operation conducted using the 2D loading map in an embodiment.

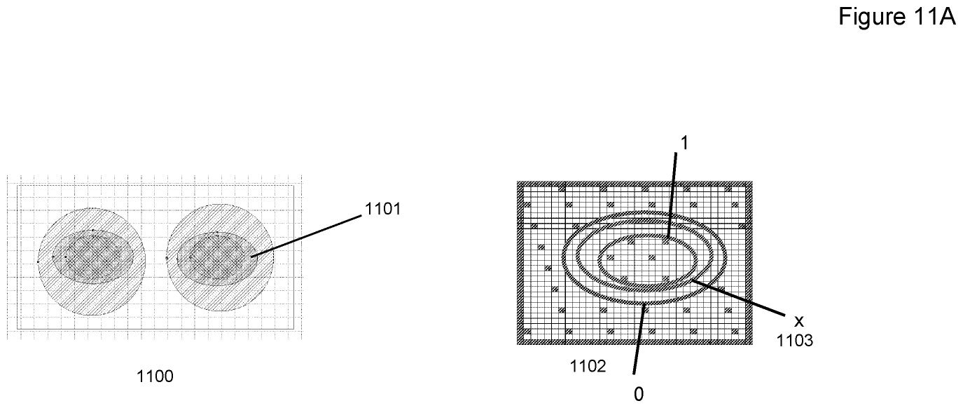

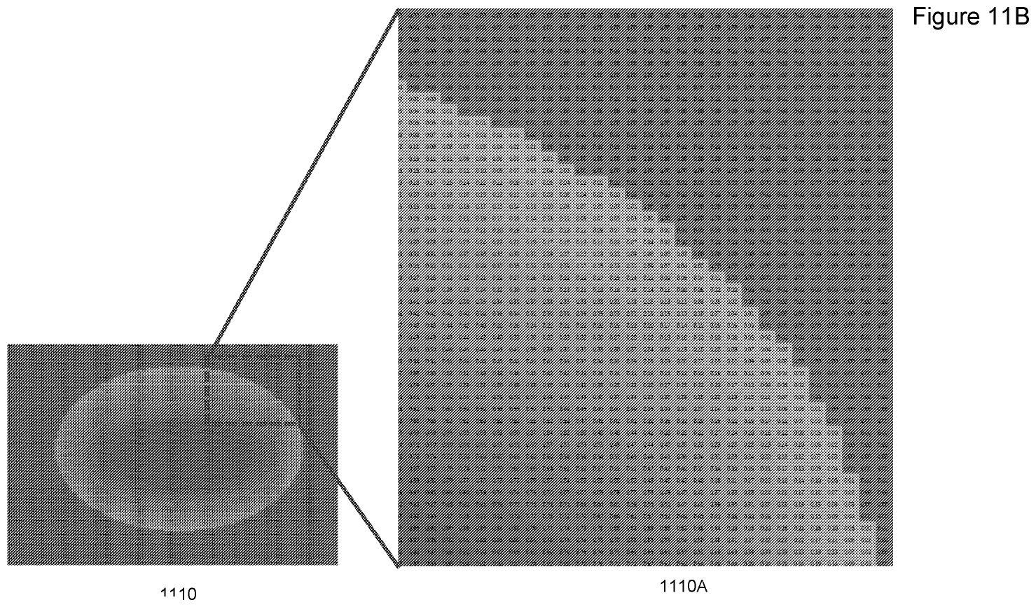

In some embodiments, one or more contour masks in addition to the top and bottom contour masks discussed above may be used to perform 3D PR profile generation. More particularly, one or more middle contour masks describing the PR profile at a middle location may be added to provide additional data from which to generate the 2D loading map. FIG. 11A depicts the use of at least one additional mask to perform 3D PR profile generation in an exemplary embodiment. Map grid 1100 of an exemplary semiconductor device structure depicts a middle mask 1101. Density map grid 1102 depicts the middle mask 1103 located between the top mask and bottom mask, at a depth of x where x is at a depth greater than 0 and less than 1. In the manner described above, off-grid edge data for the middle mask may be extracted and added to the combined density map/loading list used to construct the 2D loading map. FIG. 11B depicts an exemplary 2D loading map 1110 and exploded view of the map 1110A produced using data from the middle mask.

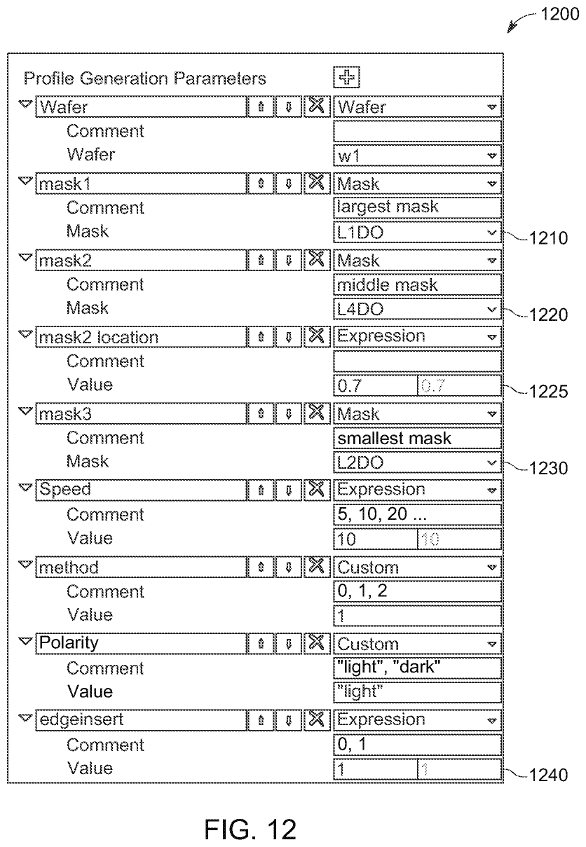

In some embodiments, the one or more middle masks at a specified depth between the top and bottom surface of the semiconductor device structure may be selected by a user via a user interface. FIG. 12 depicts a user interface for selecting parameters related to the use of at least one additional middle mask to perform 3D PR profile generation in an exemplary embodiment. For example, exemplary user interface 1200 enables a user to make selections for a largest first mask 1210, a second middle mask 1220, and a third smallest mask 1230. User interface 1200 also enables a user to select a location/depth 1225 of the second middle mask at a depth between the depths of the upper and lower masks (i.e. between 0 and 1 in the example discussed above). Although not shown, additional middle masks may also be selected by a user in some embodiments.

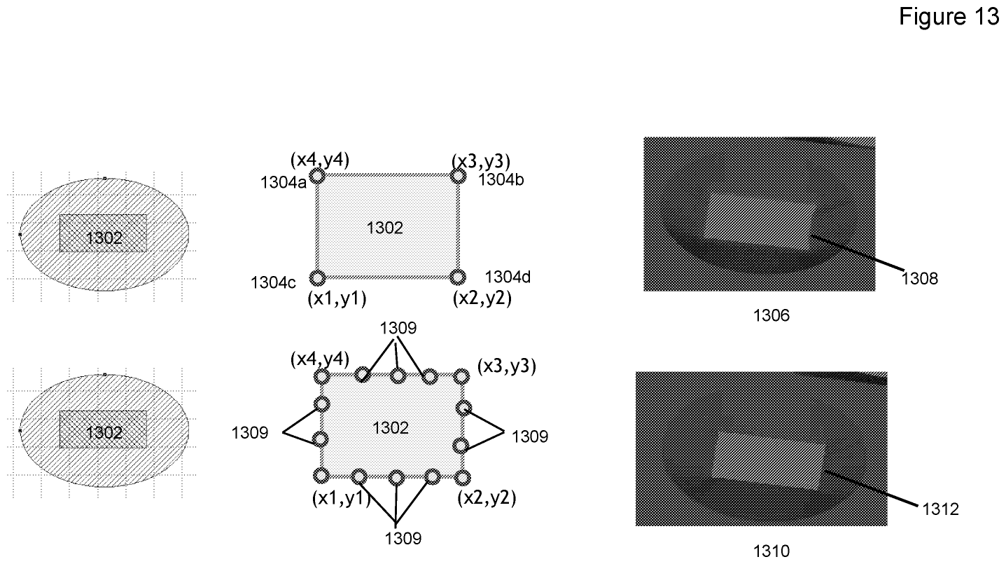

For square polygons on a mask, the number of edge coordinates is often too small for optimal interpolation. As a consequence, the resulting fabricated structure will sometimes have rounded corners and/or edges that appear significantly non-linear. To address this issue, in one embodiment, the PR profile generation module may provide a user interface that enables a user to select a parameter (e.g.: insertion parameter 1240 in FIG. 12) that inserts additional edge coordinates into the shape. FIG. 13 depicts the insertion of extra edge data and the effects of interpolating the extra edge data for square cornered polygons on a mask. As depicted, a square cornered polygon 1302 before insertion includes corner coordinates 1304a, 1304b, 1304c, 1304d. Following interpolation to produce the 2D loading map, the resulting output following the etch operation is polygon shape 1306 with an abnormal (non-linear) edge 1308. In contrast, in an embodiment where a user inserts additional edge coordinates 1309, the resulting shape 1310 includes a significantly more accurate profile with linear edge 1312.

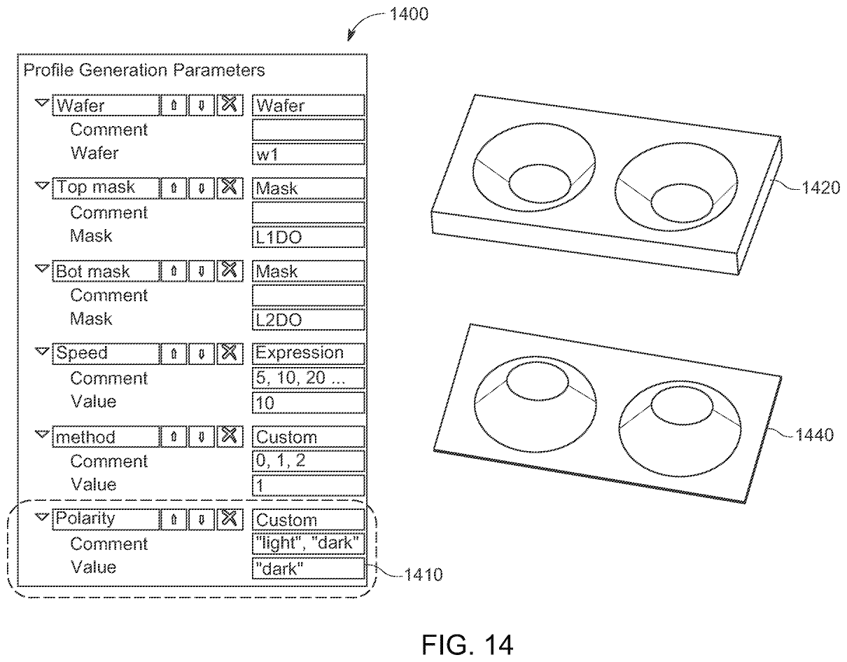

In one embodiment, a user interface may be provided to allow the user to select a dark or light mask polarity parameter. FIG. 14 depicts a user interface 1400 for selecting a mask polarity parameter 1402 to perform 3D PR profile generation in an exemplary embodiment. Structure 1420 depicts the result of selecting a light polarity parameter while structure 1440 depicts the result of selecting a dark polarity parameter.

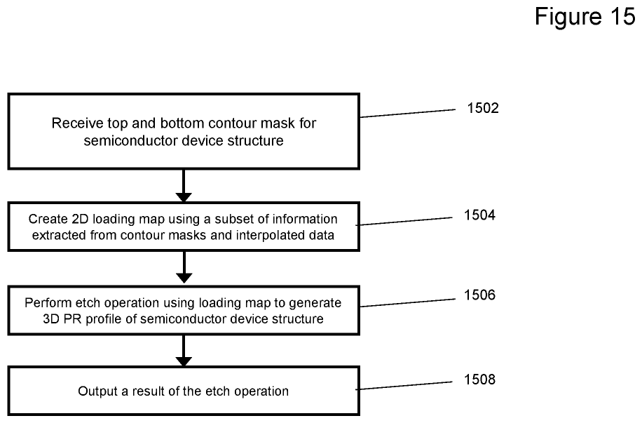

FIG. 15 depicts a sequence of steps performed in the virtual fabrication environment for 3D PR profile generation in an exemplary embodiment. The sequence begins with the receipt in the virtual fabrication environment of the top and bottom contour masks (step 1502). As discussed above, in some embodiments one or more middle contour masks may also be received. A 2D loading map is then created using an extracted subset of the contour mask on-grid data (and optionally off-grid edge data) and interpolated data based upon the extracted data (step 1504). An etch operation, controlled by the 2D loading map is performed to generate a 3D PR profile for the semiconductor device being fabricated (step 1506). A result of the etch operation may then be output such as being exported or displayed (step 1508).

It should be appreciated that the 3D Profile generation module discussed herein may be integrated into a virtual fabrication environment or provided in whole or in part via a separate plug-in or other application that works in concert with the virtual fabrication environment and description of acts taking place in the virtual fabrication environment should be understood to encompass both arrangements.

One of the benefits of the fast accurate 3D PR profile generation provided by embodiments is the ability to quickly perform Designs of Experiments (DOEs) to vary process parameters while observing the effect on the generated PR profile. In the event of a pattern failure induced by PR profile loading in a physical fab, a DOE may be quickly designed in the virtual fabrication environment to replicate the failure and explore possibilities to remedy the issue. For example, when a PR profile is tapered for a pattern, After Etching Inspection critical dimension (AEI CD) control for the pattern may be difficult since a tapered PR sidewall can act as a hard mask to partially block the etch process leading to the etch profile also being tapered.

Although the description herein has described the use of voxel-based models simulated by the virtual fabrication environment, it should be appreciated that embodiments of the present invention are not so limited. In some embodiments, the techniques described herein for 3D photoresist profile generation may be applied in virtual fabrication environments that do not rely on voxel-based representation of models.

Portions or all of the embodiments of the present invention may be provided as one or more computer-readable programs or code embodied on or in one or more non-transitory mediums. The mediums may be, but are not limited to a hard disk, a compact disc, a digital versatile disc, a flash memory, a PROM, a RAM, a ROM, or a magnetic tape. In general, the computer-readable programs or code may be implemented in any computing language.

Since certain changes may be made without departing from the scope of the present invention, it is intended that all matter contained in the above description or shown in the accompanying drawings be interpreted as illustrative and not in a literal sense. Practitioners of the art will realize that the sequence of steps and architectures depicted in the figures may be altered without departing from the scope of the present invention and that the illustrations contained herein are singular examples of a multitude of possible depictions of the present invention.

The foregoing description of example embodiments of the invention provides illustration and description, but is not intended to be exhaustive or to limit the invention to the precise form disclosed. Modifications and variations are possible in light of the above teachings or may be acquired from practice of the invention. For example, while a series of acts has been described, the order of the acts may be modified in other implementations consistent with the principles of the invention. Further, non-dependent acts may be performed in parallel.

1. A non-transitory medium holding computing device-executable instructions for performing 3D photoresist profile generation, the instructions when executed causing at least one computing device equipped with at least one processor to:
receive in a virtual fabrication environment a top contour mask that describes a photoresist profile at a top of a semiconductor device structure being fabricated and a bottom contour mask that describes a photoresist profile at a bottom of a semiconductor device structure being fabricated;
creating a loading map using a subset of density information extracted from the top contour mask and the bottom contour mask;
perform an etch operation using the loading map to generate a 3D photoresist profile for the semiconductor device structure; and
output a result of the etch operation.

2. The medium of claim 1, wherein the creation of the loading map also uses contour edge information extracted from the top contour mask and the bottom contour mask.

3. The medium of claim 2, wherein the instructions when executed cause the at least one computing device to:
receive in the virtual fabrication environment at least one additional contour mask at a depth in the semiconductor device structure being fabricated that is located between the top contour mask and bottom contour mask; and
create the loading map by also using contour edge information extracted from the at least one additional contour mask.

4. The medium of claim 3, wherein the instructions when executed cause the at least one computing device to:
perform linear interpolation for square corner polygon shapes located on one or more of the top contour mask and the bottom contour mask, to insert additional edge data points.

5. The medium of claim 1, wherein the instructions when executed cause the at least one computing device to:
generate a first density map by examining a subset of locations in the top contour mask;
generate a second density map by examining a subset of locations in the bottom contour mask; and
combine the first density map and second density map into a single map holding the subset of density information used to create the loading map.

6. The medium of claim 1, wherein the instructions when executed cause the at least one computing device to:
provide a user interface configured to receive a user-selected speed parameter controlling the size of the subset of density information extracted from top contour mask and the bottom contour mask.

7. The medium of claim 1, wherein the instructions when executed cause the at least one computing device to:
provide a user interface configured to receive a user-selected interpolation parameter indicating a type of interpolation method used to create the loading map.

8. The medium of claim 1, wherein the instructions when executed cause the at least one computing device to:
provide a user interface configured to receive a user-selected polarity parameter.

9. A computing device-implemented method for performing 3D photoresist profile generation, the method comprising:
receiving in a virtual fabrication environment a top contour mask that describes a photoresist profile at a top of a semiconductor device structure being fabricated and a bottom contour mask that describes a photoresist profile at a bottom of a semiconductor device structure being fabricated;
creating a loading map using a subset of density information extracted from the top contour mask and the bottom contour mask;
performing an etch operation using the loading map to generate a 3D photoresist profile for the semiconductor device structure being fabricated; and
output a result of the etch operation.

10. The method of claim 9, wherein the creation of the loading map also uses contour edge information extracted from the top contour mask and the bottom contour mask.

11. The method of claim 10, further comprising:
receiving in the virtual fabrication environment at least one additional contour mask at a depth in the semiconductor device structure being fabricated that is located between the top contour mask and bottom contour mask; and
creating the loading map by also using contour edge information extracted from the at least one additional contour mask.

12. The method of claim 11, further comprising:
performing linear interpolation for square corner polygon shapes on one or more of the top contour mask and the bottom contour mask, to insert additional edge data points.

13. The method of claim 9, further comprising:
generating a first density map by examining a subset of locations in the top contour mask;
generating a second density map by examining a subset of locations in the bottom contour mask; and
combining the first density map and second density map into a single map holding the subset of density information used to create the loading map.

14. The method of claim 9, further comprising:
providing a user interface configured to receive a user-selected speed parameter controlling the size of the subset of density information extracted from top contour mask and the bottom contour mask.

15. The method of claim 9, further comprising:
providing a user interface configured to receive a user-selected interpolation parameter indicating a type of interpolation method used to create the loading map.

16. The method of claim 9, further comprising:
providing a user interface configured to receive a user-selected polarity parameter.

17. A system for performing 3D photoresist profile generation, comprising:
at least one computing device equipped with one or more processors that is configured to generate a virtual fabrication environment that includes a 3D photoresist profile generation module, the 3D photoresist profile generation module when executing:
receiving in a virtual fabrication environment a top contour mask that describes a photoresist profile at a top of a semiconductor device structure being fabricated and a bottom contour mask that describes a photoresist profile at a bottom of a semiconductor device structure being fabricated,
creating a loading map using a subset of density information extracted from the top contour mask and the bottom contour mask, and
performing an etch operation using the loading map to generate a 3D photoresist profile for the semiconductor device structure being fabricated; and
a display surface communicatively coupled to the at least one computing device and configured to display a result of the etch operation.

18. The system of claim 17, wherein the creation of the loading map also uses contour edge information extracted from the top contour mask and the bottom contour mask.

19. The system of claim 17, the 3D photoresist profile generation module when executing further:
receiving in the virtual fabrication environment at least one additional contour mask at a depth in the semiconductor device structure being fabricated that is located between the top contour mask and bottom contour mask; and
creating the loading map by also using contour edge information extracted from the at least one additional contour mask.

20. The system of claim 17, the 3D photoresist profile generation module when executing further:
performing linear interpolation for square corner polygon shapes on one or more of the top contour mask and the bottom contour mask, to insert additional edge data points.
